(19) United States
(12) Patent Application Publication
(10) Pub. No.: US 2013/0161629 A1
(43) Pub. Date: Jun. 27, 2013

(54) ZERO SHRINKAGE SMOOTH INTERFACE OXY-NITRIDE AND OXY-AMORPHOUS-SILICON STACKS FOR 3D MEMORY VERTICAL GATE APPLICATION

(71) Applicants: XINHAI HAN, Sunnyvale, CA (US); NAGARAJAN RAJAGOPALAN, Santa Clara, CA (US); GUANGCHI XUAN, Sunnyvale, CA (US); JIANHUA ZHOU, Campbell, CA (US); JIGANG LI, Sunnyvale, CA (US); SHAHID SHAIKH, Santa Clara, CA (US); PATRICK REILLY, Dublin, CA (US); THOMAS NOWAK, Cupertino, CA (US); JUAN CARLOS ROCHA-ALVAREZ, San Carlos, CA (US); HEUNG LAK PARK, San Jose, CA (US); BOK HOEN KIM, San Jose, CA (US)

(72) Inventors: XINHAI HAN, Sunnyvale, CA (US); NAGARAJAN RAJAGOPALAN, Santa Clara, CA (US); GUANGCHI XUAN, Sunnyvale, CA (US); JIANHUA ZHOU, Campbell, CA (US); JIGANG LI, Sunnyvale, CA (US); SHAHID SHAIKH, Santa Clara, CA (US); PATRICK REILLY, Dublin, CA (US); THOMAS NOWAK, Cupertino, CA (US); JUAN CARLOS ROCHA-ALVAREZ, San Carlos, CA (US); HEUNG LAK PARK, San Jose, CA (US); BOK HOEN KIM, San Jose, CA (US)

(73) Assignee: APPLIED MATERIALS, INC., Santa Clara, CA (US)

(21) Appl. No.: 13/337,749

(22) Filed: Dec. 27, 2011

(51) Int. Cl. H01L 29/78; H01L 21/20

(52) U.S. Cl. 257/66; 438/488; 257/E21.09; 257/E29.262

(57) ABSTRACT

Methods are provided for depositing a stack of film layers for use in vertical gates for 3D memory devices, by depositing a sacrificial nitride film layer at a sacrificial film deposition temperature greater than about 550° C.; depositing an oxide film layer over the nitride film layer, at an oxide deposition temperature of about 600° C. or greater; repeating the above steps to deposit a film stack having alternating layers of the sacrificial films and the oxide films; forming a plurality of holes in the film stack; and depositing polysilicon in the plurality of holes in the film stack at a polysilicon process temperature of about 700° C. or greater, wherein the sacrificial film layers and the oxide film layers experience near zero shrinkage during the polysilicon deposition. Flash drive memory devices may also be made by these methods.

### BACKGROUND OF THE INVENTION

1. Field of the Invention

Aspects of the present invention generally relate to methods and devices for stacks in 3D memory vertical gate applications. Further aspects relate to low or zero shrinkage stacks achieved from smooth interfaces between alternating layers of oxide and nitride films or oxide and amorphous silicon films.

2. Description of the Related Art

Computer memory devices are ever in pursuit of smaller geometries with increased capacity at less cost. To this end, components of memory cells are stacked on top of each other to create 3D cells. One such technology is NAND flash memory, which may be found in memory cards, USB flash drives, solid-state drives and similar products, for data storage and transfer. In NAND flash memory, memory cells made from transistors are connected in series, and can be stacked into vertical layers to create densely packed, high capacity devices. With no moving parts, flash drives use less power and are more durable than ordinary hard drives. Accordingly, there is great interest in increasing the capacity of flash drives, while reducing their size and cost.

To create 3D structures for memory cells, charge trapping transistors may be stacked into vertical layers. An electrical diagram of a flash cell string 200 in a 3D structure is illustrated in FIG. 1. A flash memory device (not shown) comprises many such flash cell strings 200 for storing data. A bit line 202 is connected to an upper select gate 204 transistor, which is connected to a control gate section 206 of transistors 208(a-d) connected in series. Each of the transistors 208(a-d) has a word line 210(a-d), respectively. Control gate section 206 is then connected to the lower select gate 212 transistor, which is connected to the source line 214. As shown, multilevel devices can store more than one bit per string.

However, as flash technology has progressed, limitations exist in how to create high capacity devices on a small scale. For example, different materials that are combined on a microscopic scale have different physical properties that lead to non-uniformities in a flash memory device. Further, high heat process steps can cause the different materials to undergo volume changes at different rates. These problems can cause a deposited stack of different layers to warp. Warping problems limit the number of layers that can be effectively deposited in manufacturing, and it can reduce the number of functioning memory strings available to the overall memory device.

Nom FIG. 2 illustrates a cross section of a stack 311 of alternating film layers in which warping has occurred. In FIG. 2, a deposition process step 310 is provided, in which the stack 311 is created by depositing alternating layers of silicon oxide and silicon nitride films using plasma enhanced chemical vapor deposition (PECVD). In the deposition process, a first or bottom layer of silicon nitride 312 is deposited, followed by a first layer of silicon oxide 313, then a second layer of silicon nitride 314, followed by a second layer of silicon oxide 315. In this illustrative example, a third layer of silicon nitride 316, followed by a third layer of silicon oxide 317 are then provided.

Next, in poly-channel process step 330, a plurality of channel holes 332 are provided in stack 311 by punching through-holes in the stack. These channel holes 332 may also be referred to as poly-channel holes, because polysilicon (i.e., polycrystalline silicon) is used to fill the channels in a subsequent polysilicon deposition step 340. Thus, in step 340, polysilicon channels 342 (or poly-channels) are created by depositing polysilicon in the channel holes 332 created in step 330. The polysilicon deposition process uses very high temperatures of 700° C. and above. However, the stack 311 of alternating silicon oxide and silicon nitride films is deposited at much lower temperatures to avoid AlFₓ building up in the reactor during cleaning operations. Thus, the higher temperature polysilicon deposition process acts as an anneal and causes the silicon oxide and silicon nitride films to shrink. Since silicon oxide has different properties than silicon nitride, the films shrink at different rates, which causes the stack 311 to stress and bow, producing a warped shaped as illustrated in step 340 of FIG. 2. For example, a silicon nitride layer can shrink more than an adjacent silicon oxide layer. Moreover, layers may undergo stress changes when exposed to a high temperature anneal, which also can lead to warping. Nitride films with very high tensile stress may not have as much stress changes after anneal, but then very high shrinkage rates occur.

Warping limits the number of layers that can be stacked and can reduce the number of working memory strings that are ultimately fabricated in a memory device such as a flash drive. Stack warping can also cause variations in channel length of transistor gates, which negatively impacts memory strings. Therefore, a need exists for improved methods and devices for 3D memory structures.

### SUMMARY OF THE INVENTION

Devices and methods for 3D memory structures are provided. In one embodiment, a method is provided for depositing a stack of film layers for use in vertical gates for 3D memory devices, the method comprising a sequence of supplying one or more process gases suitable for depositing a nitride film into a processing chamber of a deposition reactor, depositing a sacrificial nitride film layer at a nitride film deposition temperature greater than about 400° C., supplying one or more process gases suitable for depositing an oxide film into a processing chamber of a deposition reactor, and depositing an oxide film layer over the nitride film layer, at an oxide deposition temperature greater than about 400° C., wherein the sequence is repeated to deposit a film stack having alternating layers of the sacrificial nitride films and the oxide films, forming a plurality of holes in the film stack, and depositing polysilicon in the plurality of holes in the film stack at a polysilicon process temperature of about 700° C. or greater, wherein the nitride film layers and the oxide film layers experience near zero shrinkage during the polysilicon deposition.

In a further embodiment, the nitride and oxide deposition temperatures are about 600° C. or greater. In a still further embodiment, a showerhead having a straight hole faceplate is used for supplying the process gases into the processing chamber. In additional embodiments, the method provides for coating at least a portion of the deposition reactor with yttrium oxide to reduce AlFₓ deposits during subsequent cleaning operations. In other embodiments, the sacrificial nitride film layers are silicon nitride and the oxide film layers are silicon oxide.

In addition, the one or more process gases used to deposit silicon nitride layers comprise silane and ammonia, and the ammonia exceeds the silane on a volumetric basis. Other embodiments provide that the ammonia is at least 100 times as much as the silane, on a volumetric basis. In further embodiments, the one or more process gases used to deposit silicon nitride layers further comprises molecular nitrogen. In additional embodiments, the process gases used to deposit silicon nitride and the process gases used to deposit silicon oxide further comprise one or more dilution gases that are inert at process conditions. In another embodiment, the one or more dilution gases is argon and/or helium. Other embodiments provide that the one or more process gases used to deposit silicon oxide comprise tetraethoxysilane, N₂O and a dilution gas that is inert at process conditions.

Another embodiment provides for a method for depositing a stack of film layers for use in vertical gates for 3D memory devices, the method comprising supplying one or more process gases suitable for depositing an amorphous silicon film into a processing chamber of a deposition reactor, depositing an amorphous silicon film layer at an amorphous silicon film deposition temperature greater than about 550° C., supplying one or more process gases suitable for depositing a silicon oxide film into a processing chamber of a deposition reactor, depositing an oxide film layer over the nitride film layer, at a silicon oxide deposition temperature greater than about 550° C., repeating the above steps to deposit a film stack having alternating layers of the amorphous silicon films and the silicon oxide films, forming a plurality of holes in the film stack, and depositing polysilicon in the plurality of holes in the film stack at a polysilicon process temperature of about 700° C. or greater, wherein the amorphous silicon film layers and the oxide film layers experience near zero shrinkage during the polysilicon deposition.

In a further embodiment, the amorphous silicon and the silicon oxide deposition temperatures are about 600° C. or greater. In a still further embodiment, a showerhead having a straight hole faceplate is used for supplying the process gases into the processing chamber. In another embodiment, the method provides for using yttrium oxide as a coating for at least a portion of the deposition reactor to reduce AlFₓ building up during subsequent cleaning operations. Other embodiments provide that the one or more process gases used to deposit silicon oxide comprise tetraethoxysilane, N₂O and a dilution gas that is inert at process conditions.

Embodiments are also disclosed for computer memory devices made by any of the above methods, whether alone or in combination with other embodiments. In one embodiment, a 3D vertical gate computer memory device is formed by a process comprising at least the steps of supplying one or more process gases suitable for depositing a sacrificial film into a processing chamber of a deposition reactor, depositing a sacrificial film layer at a sacrificial film deposition temperature greater than about 550° C., supplying one or more process gases suitable for depositing an oxide film into a processing chamber of a deposition reactor, depositing an oxide film layer over the nitride film layer, at an oxide deposition temperature greater than about 550° C., repeating the above steps to deposit a film stack having alternating layers of the sacrificial films and the oxide films, forming a plurality of holes in the film stack, and depositing polysilicon in the plurality of holes in the film stack at a polysilicon process temperature of about 700° C. or greater, wherein the sacrificial film layers and the oxide film layers experience near zero shrinkage during the polysilicon deposition.

Additional embodiments provide that the sacrificial film layers are silicon nitride, and the oxide film layers are silicon oxide. Further embodiments provide that the one or more process gases suitable for depositing the sacrificial silicon nitride layers comprise silane and ammonia, and the ammonia exceeds the silane on a volumetric basis. Still other embodiments provide that the sacrificial film and the oxide film deposition temperatures are about 600° C. or greater.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted that the appended drawings illustrate only example embodiments for discussion, and are therefore not drawn to scale and are not limiting of claim scope.

FIG. 1 illustrates an electronic diagram of a vertical flash cell string.

FIG. 2 illustrates a cross section of a stack of alternating film layers undergoing steps to create polysilicon channels, according to previous methods.

FIG. 3 illustrates a cross section of a stack of alternating film layers undergoing steps to create polysilicon channels, according to some embodiments discussed herein.

FIG. 4 illustrates a stack of alternating film layers undergoing steps to create gates, according to some embodiments herein.

It is contemplated that features of one embodiment may be beneficially incorporated in other embodiments without further recitation.

### DETAILED DESCRIPTION

Embodiments discussed herein provide for improved stacks for 3D memory devices, methods for producing 3D memory devices and apparatuses for producing 3D memory devices. Further embodiments are described for approaches to reduce and/or eliminate shrinkage in alternating film layers in a stack when those layers are exposed to a high temperature process such as an anneal.

In order to micronize memory cells in vertical 3D arrangements, film layers are deposited into a stack, which is then further processed to create arrays of string cells. Some examples discussed herein relate to a Terabit Cell Array Transistor (TCAT) flash memory structure, in which a cell string has six-NAND cell transistors. But it is to be understood that the ideas disclosed herein may be applied to other 3D or vertical gate memory structures as well. For example, other configurations may use three-dimensional Bit-Cost Scalable (BiCS) flash memory. Other flash memory devices may use pipe-shaped Bit Cost Scalable (P-BiCS) structures, in which NAND strings are folded like a U-shape so that the select-gate transistors are at the top of each end section in the “U.” Thus, the bit line is positioned at one terminal end of the “U,” and the source line is positioned at the second terminal end of the “U.” P-BiCS flash memory may use two adjacent NAND strings connected at the bottoms by a “pipe-connection”, which is gated by the bottom electrode. Additionally, orientations may be changed, such as by vertical-gate (VG) NAND, in which cell strings are positioned horizontally so that the control gate is embedded in the perpendicular direction and connected directly to the word line on the bottom layer. Other types of flash memory are also possible, such as NOR flash, in which each cell has one end connected directly to ground, and the other end connected directly to a bit line.

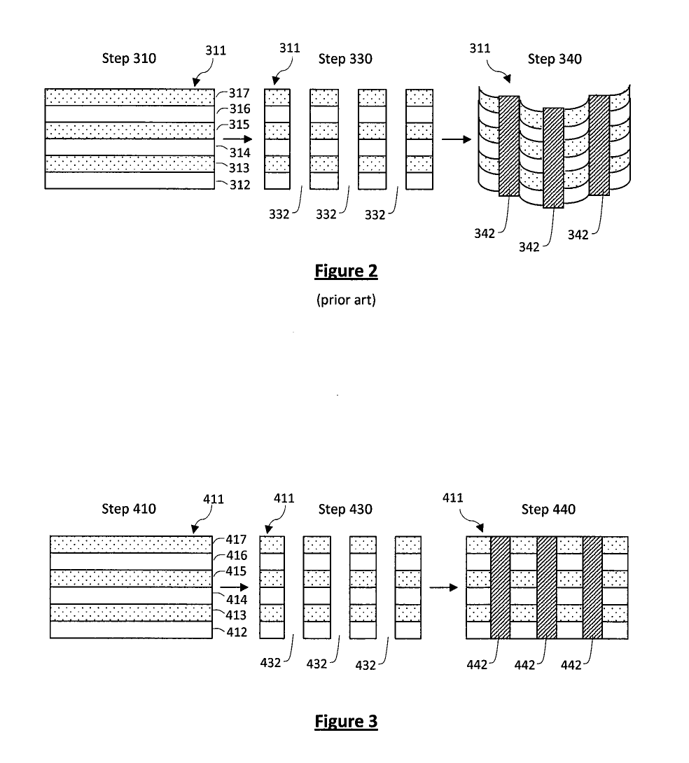

FIG. 3 illustrates a stack 411, in which the warping problem has been eliminated, according to one or more of the embodiments discussed herein. Similar to FIG. 2, FIG. 3 illustrates a deposition process step 410 to deposit alternating film layers into the stack 411. In a preferred embodiment, PECVD deposition is used, but other deposition methods are not excluded. Next, in poly-channel process step 430, a plurality of channel holes 432 are created in stack 411, such as by punching through-holes in the stack. Alternatively, cutting techniques may be used, such as dry etching. In a subsequent polysilicon deposition step 440, a plurality of polysilicon channels 442 are created by depositing polysilicon in the channel holes 432, but without warping the stack 411.

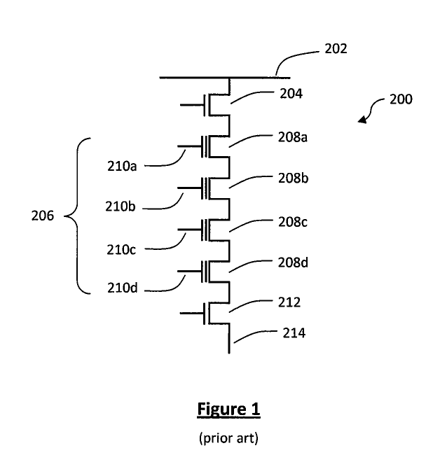

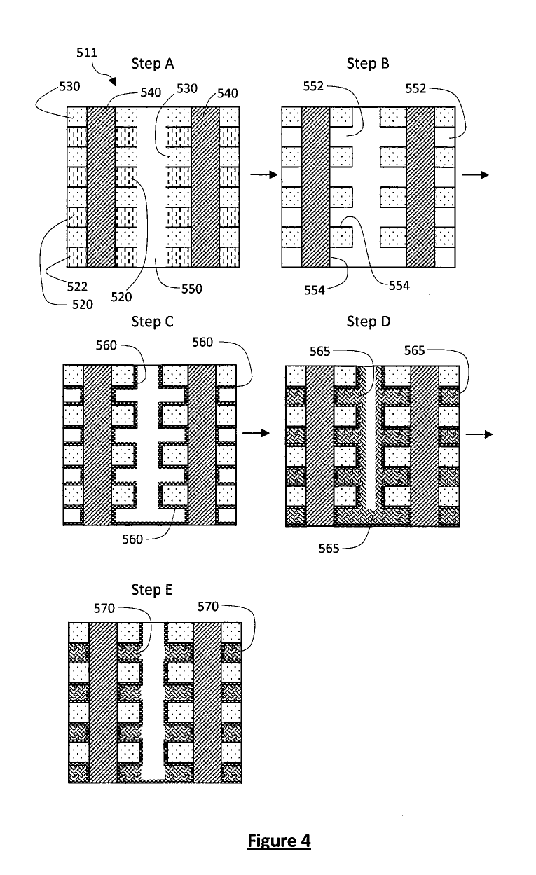

The stack 411 may comprise alternating layers of oxide and nitride films. The oxide layer may be a silicon oxide. The nitride layer may be a silicon nitride. Silicon oxide may comprise SiO, although SiO₂ and mixtures of SiO and SiO₂ are not excluded. Silicon nitride may comprise SiN, although Si₃N₄, other molecular formulations and mixtures of the same are not excluded. Additionally, embodiments discussed herein also allow for use of alternating layers of silicon oxide and amorphous silicon (a-Si) to form a stack. In this illustrative example, a first or bottom layer of silicon nitride 412 is deposited, followed by a first layer of silicon oxide 413, then a second layer of silicon nitride 414, followed by a second layer of silicon oxide 415, followed by a third layer of silicon nitride 416, and then a third layer of silicon oxide 417. It should be understood that additional layers will also be provided in practice. Further, the top layer may also comprise a silicon nitride film (not shown). Alternatively, the bottom layer may be a silicon oxide. As will be discussed below for FIG. 4, in subsequent process steps, the nitride layers can be etched away and replaced with metal gates, isolated by a dielectric material, to form memory strings such as provided in FIG. 1. Thus, the selection of the number and the arrangement of layers may be based on the number and arrangement of gates that are desired in memory strings. For a TCAT structure, the gates may include both a middle section of control gates with one or more selection gates on top and on bottom. In a-Si stacks, the silicon layer may be not be sacrificed like the nitride layers in the oxide-nitride stacks. Instead, the a-Si layer may be used as a control gate, and the a-Si layer may be highly doped to reduce resistivity.

Various techniques have been discovered that reduce and/or eliminate the warping effect, which are discussed in the embodiments presented herein. These embodiments may further be combined to provide even greater process uniformity and to provide increased margins for error in manufacturing. Further, eliminating stack warping allows for increasing the number of gates and/or decreasing the size of channel length for such gates.

In one embodiment, high temperature deposition of oxide and nitride layers achieve near zero shrinkage when exposed to high temperature process steps such as the polysilicon anneal. Near zero shrinkage of a film layer means that the change in thickness before and after high temperature exposure (e.g., 700° C. and above) is less than about 0.3%. Near zero shrinkage rates were seen in oxide layers, nitride layers and amorphous silicon layers. This is a significant improvement over previous methods, in which a silicon nitride layer may shrink in thickness about 2.4%, whereas a silicon oxygen layer would shrink in thickness about 1%. Moreover, near zero or zero stress changes may be achieved in addition to near zero or zero shrinkage rates. Further, obtaining near zero shrinkage rates in different layers reduces interface stresses because even if there is some small amount of shrinkage, it is much less and more uniform across the stack.

As discussed above, the polysilicon deposition process may involve temperatures of about 700° C. and above. To deposit the alternating film layers in stack 411, a PECVD chamber may be used to deposit the films at temperatures over 500° C. In further embodiments, film layers may be deposited at temperatures over about 550° C. Preferably, temperatures of about 600° C. and greater are used to deposit the film layers in the stack 411. In a further embodiment, temperatures of about 650° C. are used to deposit the film layers. In still further embodiments, the film layers in the stack 411 may be deposited at temperatures near the temperature of the polysilicon process, such as temperatures that vary less than 15% or 10% or even 5% from the temperature of the polysilicon process. In other embodiments, temperatures of about 400° C. and above may be used. Temperatures in ranges of 400° C. and above may be combined with other embodiments discussed herein, as exemplified in Tables 1, 2 and 3 below.

It has been discovered that the high-temperature deposited films in the stack 411 have higher density and reduced hydrogen content than in the past. This is especially critical to reducing warping in the stack 411, since higher density films with less hydrogen have less opportunity to shrink when exposed to a high temperature anneal. This further reduces interface stresses between the alternating layers. When combined into a stack, increased interface stresses between multiple layers lead to warping, such as shown in FIG. 2. By depositing film layers with higher density and less hydrogen content, shrinkage rates are reduced during the high temperature anneal, and interface stresses are reduced as well. In the high temperature anneal process shown in FIG. 2, interface stresses may increase by 100 or 200 MPa. In contrast, the process shown in FIG. 3 may involve near zero stress changes after anneal, for example less than about 20 MPa. Moreover, both near zero shrinkage and near zero stress changes may be achieved. This provides a significant improvement over the prior art.

As discussed above, the reason previous deposition methods use low temperatures is to avoid AlFₓ building up in the reactor during cleaning operations. AlF₃ is used to provide cleaning, and is known to leave deposits behind when higher temperatures are used. In order to avoid these problems with higher temperatures, a coated heater may be used in the PECVD process to run at temperatures over 600° C. with minimum AlFₓ build-up during cleaning. A coating may be selected that is resistant to floride. In one embodiment, an oxide compound is used for the coating. In a further embodiment, yttrium oxide is used to coat the reactor. In another embodiment, yttrium oxide is used to coat parts of a PECVD reactor used for heating, such as the plasma electrodes.

Additional embodiments reduce the surface roughness of the film layers in the stack 411. Faceplate engineering can improve roughness. Embodiments have been discovered to alter ion bombardment in ways that make the film surfaces smoother or that reduce interface roughness. These embodiments are applicable to oxide and nitride layers as well as to a-Si layers. In one example, a showerhead having a conical hole faceplate in a PECVD reactor was replaced with a straight hole faceplate. The linear holes resulted in a smoother surface on the top layer deposited, which resulted in less stress at the interface between the next deposited layer.

Providing a smooth surface was found to be critical, because the top surface of the stack becomes rougher as more layers are added. When successive layers are deposited on a rough surface, the roughness measurements are compounded as the stack grows. By reducing surface roughness of each film layer, more layers can be uniformly deposited.

Further, the straight hole faceplate embodiment can be combined with embodiments to modify the ratio of reactive species in the PECVD process. It has been discovered that a high ammonia (NH₃) to silane (SiH₄) ratio reduced the surface roughness of silicon nitride films, and reduced the interface roughness between silicon nitride and silicon oxide. Moreover, both near zero shrinkage and near zero stress changes may be achieved. Previously, a 1:2 silane to ammonia ratio was used to deposit the silicon nitride layers. In one embodiment, the silane to ammonia ratio may be altered so that there is more ammonia than silane on a volumetric basis. In a further embodiment, 100 to 200 times as much ammonia is used as silane. Molecular nitrogen (N₂) may also be added to the gas mixture used in the reactor. In some embodiments, there is less N₂ than NH₃. In other embodiments, 10 to 20 times as much N₂ as NH₃ may be used.

Moreover, when films are deposited so as to experience near zero or zero shrinkage, non-reactive dilution gases can be added to the deposition process to make the films more stable. Dilution gases may be used for depositing layers of oxides, nitrides or amorphous silicon. In some embodiments, Argon or Helium may be added as a diluting agent to the reactive species in a plasma. Further, it has been found that using inert plasmas such as Argon or Helium lowers the stress close to neutral. For example, a dense nitride layer may be very tensile. The inert diluting agents reduce the internal stresses in the nitride layer. This features allows for zero or near zero stress changes to be achieved when the stack 411 is exposed to a high temperature anneal. Accordingly, both zero shrinkage and zero stress changes may be achieved. Additionally, refractive index may be measured to examine stresses in one or more layers. Thus, stresses may be measured as a function of the refractive index.

Additionally, in some embodiments, the various techniques discussed herein may be combined without using temperatures above 500° C. for the deposition. Thus, temperatures may be used in a range of about 400° C. to about 650° C. Example ranges of process parameters for the films are provided in the three tables below. Table 1 provides process conditions for deposition of oxide films to be used in an oxide/nitride or oxide/silicon stack. Table 2 provides process conditions for deposition of nitride films to be used in oxide/nitride stacks. Table 3 provides process conditions for deposition of silicon films to be used in oxide/silicon stacks with tunable doping. In these tables, HF means high frequency, LF means low frequency, TEOS means tetraethoxysilane, TMB means trimethylboron. In Table 3, TMB and B₂H₆ can be used for boron doped a-Si, and PH₃ can be used for phosphorous doped a-Si films.

TABLE 1
Deposition of Oxide Films

| | |
|---|---|
| Temperature | 400° C.-650° C. |
| Pressure | 0.5 T-10 T |
| Spacing | 200 mils-800 mils |
| HF Power | 50 W-1000 W |
| LF Power | 25 W-300 W |
| TEOS | 500 mgm-5000 mgm (or SiH4: 20 |
| | sscm-800 sccm) |
| N2O | 1000 sscm-20000 sccm |
| He | 1000 sccm-15000 sccm, and/or |
| and/or Ar | 500 sccm-5000 sccm |

TABLE 2
Deposition of Nitride Films

| | |
|---|---|
| Temperature | 400° C.-650° C. |
| Pressure | 0.5 T-10 T |
| Spacing | 300 mils-1100 mils |
| HF Power | 150 W-1000 W |
| SiH4 | 20 sscm-1000 sccm |
| NH3 | 200 sscm-15000 sccm |
| N2 | 2000 sccm-30000 sccm |
| Ar | 500 sccm-5000 sccm, and/or |
| and/or He | 500 sccm-5000 sccm |

TABLE 3
Deposition of Silicon Films

| | |
|---|---|
| Temperature | 400° C.-650° C. |
| Pressure | 0.5 T-10 T |
| Spacing | 200 mils-800 mils |
| HF Power | 50 W-1500 W |
| SiH4 | 50 sscm-2000 sccm |
| TMB (diluted in He or H2 or Ar) | 20-1000 sccm |
| B2H6 (diluted in He or H2 or Ar) | 20-1000 sccm |
| PH3 (diluted in He or H2 or Ar) | 20-1000 sccm |
| He | 1000 sccm-30000 sccm |

The embodiments discussed herein to reduce surface roughness (whether used alone or combined with one or more of the other techniques discussed below) allow targeting specific surface roughness metrics for quality. For example, previous surface roughness was found to be about 4-5 nm RMS on a top surface. To maintain low interface stress, a top surface roughness may be targeted of about 3 nm RMS or less, and preferably 1-2 nm RMS. Further, the techniques discussed herein to reduce surface roughness also may be used for other alternating layers besides nitrides and oxides. For example, the stack 411 could also use alternating layers of silicon oxide and amorphous silicon.

Moreover, by substantially reducing or eliminating stack warping, variability in channel length of later formed gates can also be reduced or eliminated. So that the importance of eliminating warping can be better understood, four additional process steps to form metal gates in a stack are shown in FIG. 4. These steps can be used to make memory strings in a TCAT flash memory device. It should be understood that this is one example, which benefits from the embodiments disclosed herein.

FIG. 4 shows a close up view of a portion of a stack 511, in which alternating layers have been deposited of silicon nitride films 520 and silicon oxide films 530, according to one or more of the embodiments discussed herein to eliminate warping in the stack. (Alternatively, silicon oxide and amorphous silicon can be used.) Channels are provided, such as polysilicon channel 540, extending vertically through the film layers. The polysilicon channels 540 function as electrodes. Accordingly, the film layers illustrated in FIG. 4 have already been exposed to a high temperature polysilicon deposition step, without warping of the layers. Therefore, the layers 520 and 530 have uniform thicknesses and smooth interfaces. Further, in this example, the bottom film layer 522 is composed of silicon nitride. Eight total film layers are illustrated in FIG. 4, but it should be understood that additional layers will be provided in practice. In some embodiments, sufficient layers are provided to have a section of six control gates, with two selection gates (one selection gate above the control gate section, and one selection gate below the control gate section). In other embodiments, stacks having about 15-17 total layers are provided. In further embodiments, the reduction/elimination of warping allows for more layers to be deposited. For example, twenty or more film layers may be deposited. In additional embodiments, forty or more film layers may be deposited.

In process step “A,” a plurality of word line cuts are made in the stack 511, such as illustrated by word line cut 550. The word line cuts may be made by a dry etching process. The word line cut 550 exposes vertical edges of the alternating stack layers 520 and 530 for further processing. The word line cuts 550 open an area for later steps that make word line connections to subsequently deposited metal gates. Next, in process step “B,” the exposed portion of the silicon nitride film is removed, such as by a wet etching step. This leaves gaps 552, having an exposed surface 554, between the oxide layers 530, and bordered on one side by the polysilicon channel 540.

Afterwards, in process step “C,” a gate dielectric film 560 is deposited on the exposed surface 554. The gate dielectric may comprise a tunnel oxide film, which is deposited on the exposed surface 554 of the silicon oxide layers 530 and the polysilicon channel 540. The gate dielectric 560 does not fill the entirety of gaps 552. Next, in step “D,” a gate material 565 is deposited in the gaps 552. The gate material may be a metal or metal alloy. A preferred material for TCAT structures is tungsten. Tungsten alloys may be used as well. Step D illustrates that excess metal may be deposited so that the metal overlaps all exposed surfaces of the dielectric. Excess metal may be removed in step “E,” forming metal gates 570, which are isolated from each other, and separated from the polysilicon electrode 540 by the dielectric film 560. The metal gates 570 serve as control gates for the word lines in the memory strings. Additionally, one or more gates at the top and also at the bottom of the stack 411 may be used as selection gates for the memory string.

It should be appreciated from FIG. 4 that eliminating warping problems in the film layer is very important to creating uniform components in the device. For example, the gate dielectric 560 can be deposited so that it is even on all sides. The gate dielectric 560 can also be deposited so that it is evenly deposited on both sides of the polysilicon channel 540, such that corresponding horizontal portions on opposite sides of the polysilicon channel 540 are on the same horizontal plane. Further, corresponding gates on the same stack level (i.e., having the same vertically numbered position) are aligned in the same horizontal plane. This allows electrons to move uniformly in memory strings, and allows the creation of a better device.

While the foregoing is directed to embodiments of the present invention, other and further embodiments of the invention may be devised without departing from the basic scope thereof, and the scope thereof is determined by the claims that follow.

1. A method for depositing a stack of film layers for use in vertical gates for 3D memory devices, the method comprising:
a sequence of:
supplying one or more process gases suitable for depositing a nitride film into a processing chamber of a deposition reactor;
depositing a sacrificial nitride film layer at a nitride film deposition temperature greater than about 400° C.;
supplying one or more process gases suitable for depositing an oxide film into a processing chamber of a deposition reactor; and
depositing an oxide film layer over the nitride film layer, at an oxide deposition temperature greater than about 400° C.;
wherein the sequence is repeated to deposit a film stack having alternating layers of the sacrificial nitride films and the oxide films;
forming a plurality of holes in the film stack; and
depositing polysilicon in the plurality of holes in the film stack at a polysilicon process temperature of about 700° C. or greater, wherein the nitride film layers and the oxide film layers experience near zero shrinkage during the polysilicon deposition.

2. The method of claim 1, wherein the nitride and oxide deposition temperatures are about 600° C. or greater.

3. The method of claim 2, wherein a showerhead having a straight hole faceplate is used for supplying the process gases into the processing chamber.

4. The method of claim 3, further comprising coating at least a portion of the deposition reactor with yttrium oxide to reduce AlFₓ deposits during subsequent cleaning operations.

5. The method of claim 1, wherein the sacrificial nitride film layers are silicon nitride and the oxide film layers are silicon oxide.

6. The method of claim 5, wherein the one or more process gases used to deposit silicon nitride layers comprise silane and ammonia, and the ammonia exceeds the silane on a volumetric basis.

7. The method of claim 6, wherein the ammonia is at least 100 times as much as the silane, on a volumetric basis.

8. The method of claim 7, wherein the one or more process gases used to deposit silicon nitride layers further comprises molecular nitrogen.

9. The method of claim 8, wherein the process gases used to deposit silicon nitride and the process gases used to deposit silicon oxide further comprise one or more dilution gases that are inert at process conditions.

10. The method of claim 9, wherein the one or more dilution gases is argon and/or helium.

11. The method of claim 10, wherein the one or more process gases used to deposit silicon oxide comprise tetraethoxysilane, N₂O and a dilution gas that is inert at process conditions.

12. A method for depositing a stack of film layers for use in vertical gates for 3D memory devices, the method comprising:
supplying one or more process gases suitable for depositing an amorphous silicon film into a processing chamber of a deposition reactor;
depositing an amorphous silicon film layer at an amorphous silicon film deposition temperature greater than about 550° C.;
supplying one or more process gases suitable for depositing a silicon oxide film into a processing chamber of a deposition reactor;
depositing an oxide film layer over the nitride film layer, at a silicon oxide deposition temperature greater than about 550° C.;
repeating the above steps to deposit a film stack having alternating layers of the amorphous silicon films and the silicon oxide films;
forming a plurality of holes in the film stack; and
depositing polysilicon in the plurality of holes in the film stack at a polysilicon process temperature of about 700° C. or greater, wherein the amorphous silicon film layers and the oxide film layers experience near zero shrinkage during the polysilicon deposition.

13. The method of claim 12, wherein the amorphous silicon and the silicon oxide deposition temperatures are about 600° C. or greater.

14. The method of claim 13, wherein a showerhead having a straight hole faceplate is used for supplying the process gases into the processing chamber.

15. The method of claim 14, further comprising using yttrium oxide as a coating for at least a portion of the deposition reactor to reduce AlFₓ building up during subsequent cleaning operations.

16. The method of claim 14, wherein the one or more process gases used to deposit silicon oxide comprise tetraethoxysilane, N₂O and a dilution gas that is inert at process conditions.

17. A 3D vertical gate computer memory device formed by a process comprising at least the steps of:
supplying one or more process gases suitable for depositing a sacrificial film into a processing chamber of a deposition reactor;
depositing a sacrificial film layer at a sacrificial film deposition temperature greater than about 550° C.;
supplying one or more process gases suitable for depositing an oxide film into a processing chamber of a deposition reactor;
depositing an oxide film layer over the nitride film layer, at an oxide deposition temperature greater than about 550° C.;
repeating the above steps to deposit a film stack having alternating layers of the sacrificial films and the oxide films;
forming a plurality of holes in the film stack; and
depositing polysilicon in the plurality of holes in the film stack at a polysilicon process temperature of about 700° C. or greater, wherein the sacrificial film layers and the oxide film layers experience near zero shrinkage during the polysilicon deposition.

18. The device of the process of claim 17, wherein the sacrificial film layers are silicon nitride, and the oxide film layers are silicon oxide.

19. The device of the process of claim 18, wherein the one or more process gases suitable for depositing the sacrificial silicon nitride layers comprise silane and ammonia, and the ammonia exceeds the silane on a volumetric basis.

20. The device of the process of claim 17, wherein the sacrificial film and the oxide film deposition temperatures are about 600° C. or greater.
